(19) United States
(12) Patent Application Publication
(10) Pub. No.: US 2026/0227718 A1
(43) Pub. Date: Aug. 6, 2026

(54) TOPOLOGY OPTIMIZED ALIGNMENT MARKS

(71) Applicant: ASML Netherlands B.V., Veldhoven (NL)

(72) Inventors: Saman JAHANI, Stamford, CT (US); Roxana REZVANI NARAGHI, Easton, CT (US); Nikhil MEHTA, Wilton, CT (US)

(73) Assignee: ASML Netherlands B.V., Veldhoven (NL)

(21) Appl. No.: 19/151,214

(22) PCT Filed: Jan. 19, 2024
(86) PCT No.: PCT/EP2024/051275

§ 371 Date: Jul. 25, 2025

Related U.S. Application Data
(60) Provisional application No. 63/483,711, filed on Feb. 7, 2023.

(51) Int. Cl. G03F 9/00; G01B 11/27

(52) U.S. Cl. CPC G03F 9/708; G01B 11/27; G03F 9/7076

(57) ABSTRACT

Disclosed is a method for an inverse design method for topology optimized alignment marks. A first alignment mark to be used on a substrate is produced, such that the first alignment mark has a topology of at least two pixels with different properties. One or more properties of each of the at least two pixels is determined. The topology of the first alignment mark is optimized based on the one or more properties of the at least two pixels. A second alignment mark, based on optimizing the first alignment mark, is formed on the substrate.

### CROSS-REFERENCE TO RELATED APPLICATION

This application claims priority of U.S. application 63/483,711 which was filed on 7 Feb. 2023 and which is incorporated herein in its entirety by reference.

### TECHNICAL FIELD

The present disclosure relates to alignment marks, for example, a general framework for designing topology optimized alignment marks using an inverse design method to discover highly complex alignment marks with optimum performance in lithographic apparatuses and systems.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which can be a mask or a reticle, can be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (photoresist or simply “resist”) provided on the substrate. In general, a single substrate will contain a network of adjacent target portions that are successively patterned. Known lithographic apparatuses include so-called steppers, in which each target portion is irradiated by exposing an entire pattern onto the target portion at one time, and so-called scanners, in which each target portion is irradiated by scanning the pattern through a radiation beam in a given direction (the “scanning”-direction) while synchronously scanning the target portions parallel or anti-parallel to this scanning direction. It is also possible to transfer the pattern from the patterning device to the substrate by imprinting the pattern onto the substrate.

During lithographic operation, different processing steps can entail different layers to be sequentially formed on the substrate. Accordingly, it can be necessary to position the substrate relative to prior patterns formed thereon with a high degree of accuracy. Generally, alignment marks are placed on the substrate to be aligned and are located with reference to a second object. A lithographic system can use an alignment apparatus for detecting positions of the alignment marks and for aligning the substrate using the alignment marks to ensure accurate exposure from a mask. Misalignment between the alignment marks at two different layers is measured as overlay error.

In order to monitor the lithographic process, parameters of the patterned substrate are measured. Parameters can include, for example, the overlay error between successive layers formed in or on the patterned substrate and critical linewidth of developed photosensitive resist. This measurement can be performed on a product substrate and/or on a dedicated metrology target. There are various techniques for making measurements of the microscopic structures formed in lithographic processes, including the use of scanning electron microscopes and various specialized tools. A fast and non-invasive form of a specialized inspection tool is a scatterometer in which a beam of radiation is directed onto a target on the surface of the substrate and properties of the scattered or reflected beam are measured. By comparing the properties of the beam before and after it has been reflected or scattered by the substrate, the properties of the substrate can be determined. This can be done, for example, by comparing the reflected beam with data stored in a library of known measurements associated with known substrate properties. Spectroscopic scatterometers direct a broadband radiation beam onto the substrate and measure the spectrum (intensity as a function of wavelength) of the radiation scattered into a particular narrow angular range. By contrast, angularly resolved scatterometers use a monochromatic radiation beam and measure the intensity of the scattered radiation as a function of angle.

Such optical scatterometers can be used to measure parameters, such as critical dimensions of developed photosensitive resist or overlay error (OV) between two layers formed in or on the patterned substrate. Properties of the substrate can be determined by comparing the properties of an illumination beam before and after the beam has been reflected or scattered by the substrate.

Conventional alignment mark design techniques focus, for example, on using known materials and optimizing the electromagnetic response of the alignment mark based on Maxwell's Equations. However, increasingly complex fabrication demands require more complex alignment marks to more precisely align the substrate. Conversely, the desire to implement faster scanning algorithms (e.g., diagonal scanning or the like) to increase processing throughput requires quicker scanning of more and smaller alignment marks. One of ordinary skill in the art will appreciate that these criteria create a trade-off that affects the overall performance of an alignment mark. These competing factors make conventional alignment mark design techniques intractable, if not impossible.

### SUMMARY

Given the above constraints, exemplary lithographic systems as described herein may be configured using an inverse design method framework to optimize a topology for an alignment mark, to discover highly complex alignment marks that nonetheless provide optimum performance in lithographic systems.

According to one aspect, the complexity of alignment marks may be characterized by alignment mark definition parameters, which may include, but are not limited to, a mark size, a grating pitch, a scan speed, a pupil map, or the like. Likewise, alignment mark scan performance may be characterized by alignment mark performance parameters, which may include, but are not limited to, alignment precision, process accuracy, product crosstalk, lateral scan offset, or the like. A set of Key Performance Indicators (KPIs) may be used to characterize the resulting overall performance of an alignment mark. Such KPIs may include, but are not limited to, alignment measurement reproducibility, a scan-offset that may cause an alignment error due to wafer deformation and coarse wafer alignment (COWA) accuracy, a six-degrees-of-freedom accuracy (6DOF) that measures an alignment position deviation (APD) caused by defocus and or local tilt of the wafer or the mark, and layer thickness that may measure an APD caused by layer thickness variation.

In some embodiments, a method may comprise producing a first alignment mark to be used on a substrate. The first alignment mark may comprise a topology of at least two pixels having different properties. The method may comprise determining one or more properties of each of the at least two pixels. The method may also comprise optimizing the topology of the first alignment mark based on the one or more properties of the at least two pixels. The method may further comprise forming a second alignment mark, based on optimizing the first alignment mark, on the substrate.

In some embodiments, a metrology system may comprise an illumination system, a projection system, and a detector. The illumination system may be configured to generate a beam of radiation. The projection system may be configured to project the beam of radiation onto an alignment mark on a substrate. The detector may be configured to detect a position of the substrate by measuring a position of the alignment mark by measuring radiation diffracted by the alignment mark. The alignment mark may comprise an optimized topology defined by at least two pixels having different properties.

In some embodiments, an alignment mark may be formed on a substrate according to embodiments disclosed herein. In some embodiments, a lithographic system may comprise a metrology system according to embodiment disclosed herein.

In some embodiments, a method may comprise receiving a first alignment mark to be used on a substrate. The first alignment mark may comprise a topology of at least two pixels having different properties. The method may comprise determining one or more properties of each of the at least two pixels. The method may comprise optimizing the topology of the first alignment mark based on the one or more properties of the at least two pixels. The method may comprise storing or displaying a set of values used to form a second alignment mark having the optimized topology.

In some embodiments, a non-transitory computer readable medium may comprise a set of instructions that, when executed by a processor, cause the processor to execute operations. The operations may comprise receiving a first alignment mark to be used on a substrate, the first alignment mark comprising a topology of at least two pixels having different properties. The operations may comprise determining one or more properties of each of the at least two pixels. The operations may comprise optimizing the topology of the first alignment mark based on the one or more properties of the at least two pixels. The operations may comprise storing or displaying a set of values used to form a second alignment mark having the optimized topology.

In some embodiments, a processor may be configured to receive a proposed alignment mark to be used on a substrate, the proposed alignment mark comprising a topology of at least two pixels having different properties. The processor may be configured to determine one or more properties of each of the at least two pixels. The processor may be configured to optimize the topology of the proposed alignment mark based on the one or more properties of the at least two pixels. The processor may be configured to store or display a set of values used to form an alignment mark having the optimized topology.

Further features of various aspects of the present disclosure are described in detail below with reference to the accompanying drawings. It is noted that the present disclosure is not limited to the specific aspects described herein. Such aspects are presented herein for illustrative purposes only. Additional aspects will be apparent to those skilled in the relevant art(s) based on the teachings contained herein.

### BRIEF DESCRIPTION OF THE DRAWINGS/FIGURES

The accompanying drawings, which are incorporated herein and form part of the specification, illustrate the present disclosure and, together with the description, further serve to explain the principles of the present disclosure and to enable those skilled in the relevant art(s) to make and use aspects described herein.

FIG. 1A shows a reflective lithographic apparatus, according to some aspects.

FIG. 1B shows a transmissive lithographic apparatus, according to some aspects.

FIG. 2 shows more details of a reflective lithographic apparatus, according to some aspects.

FIG. 3 shows a lithographic cell, according to some aspects.

FIGS. 4A and 4B show inspection apparatuses, according to some aspects.

FIG. 5 shows a schematic representation of an alignment mark, and an enlarged portion of the alignment mark, produced using an inverse design method according to some embodiments.

FIGS. 6A and 6B show two different schematic configurations of alignment marks produced using inverse design methods according to some embodiments.

FIG. 7 shows an example computer system useful for implementing various embodiments, according to some embodiments.

The features of the present disclosure will become more apparent from the detailed description set forth below when taken in conjunction with the drawings, in which like reference characters identify corresponding elements throughout. In the drawings, like reference numbers generally indicate identical, functionally similar, and/or structurally similar elements. Additionally, generally, the left-most digit(s) of a reference number identifies the drawing in which the reference number first appears. Unless otherwise indicated, the drawings provided throughout the disclosure should not be interpreted as to-scale drawings.

### DETAILED DESCRIPTION

The aspects described herein, and references in the specification to “one aspect,” “an aspect,” “an exemplary aspect,” “an example aspect,” etc., indicate that the aspects described can include a particular feature, structure, or characteristic, but every aspect may not necessarily include the particular feature, structure, or characteristic. Moreover, such phrases are not necessarily referring to the same aspect. Further, when a particular feature, structure, or characteristic is described in connection with an aspect, it is understood that it is within the knowledge of those skilled in the art to effect such feature, structure, or characteristic in connection with other aspects whether or not explicitly described.

Spatially relative terms, such as “beneath,” “below,” “lower,” “above,” “on,” “upper” and the like, can be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus can be otherwise oriented (rotated 90 degrees or at other orientations) and the spatially relative descriptors used herein can likewise be interpreted accordingly.

The terms “about,” “approximately,” or the like can be used herein to indicate the value of a given quantity that can vary based on a particular technology. Based on the particular technology, the terms “about,” “approximately,” or the like can indicate a value of a given quantity that varies within, for example, 10-30% of the value (e.g., ±10%, ±20%, or ±30% of the value).

Aspects of the present disclosure can be implemented in hardware, firmware, software, or any combination thereof. Aspects of the disclosure can also be implemented as instructions stored on a computer-readable medium, which can be read and executed by one or more processors. A machine-readable medium can include any mechanism for storing or transmitting information in a form readable by a machine (e.g., a computing device). For example, a machine-readable medium can include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Furthermore, firmware, software, routines, and/or instructions can be described herein as performing certain actions. However, it should be appreciated that such descriptions are merely for convenience and that such actions result from computing devices, processors, controllers, or other devices executing the firmware, software, routines, instructions, etc. The term “machine-readable medium” can be interchangeable with similar terms, for example, “computer program product,” “computer-readable medium,” “non-transitory computer-readable medium,” or the like. The term “non-transitory” can be used herein to characterize one or more forms of computer readable media except for a transitory, propagating signal.

Before describing such aspects in more detail, however, it is instructive to present an example environment in which aspects of the present disclosure can be implemented.

### Example Lithographic Systems

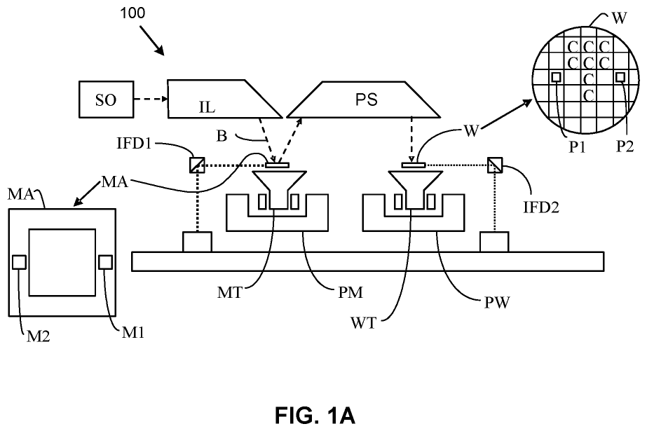

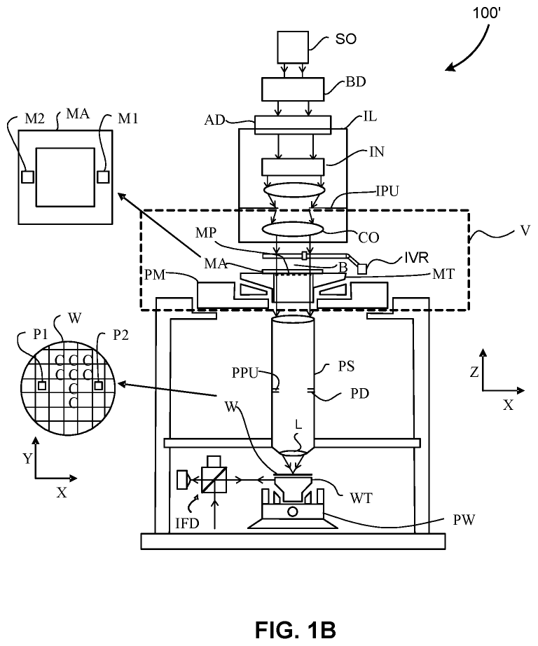

FIGS. 1A and 1B show a lithographic apparatus 100 and a lithographic apparatus 100′, respectively, in which aspects of the present disclosure can be implemented. Lithographic apparatus 100 and lithographic apparatus 100′ each include the following: an illumination system (illuminator) IL configured to condition a radiation beam B (for example, deep ultra violet or extreme ultra violet radiation); a support structure (for example, a mask table) MT configured to support a patterning device (for example, a mask, a reticle, or a dynamic patterning device) MA and connected to a first positioner PM configured to accurately position the patterning device MA; and, a substrate table (for example, a wafer table) WT configured to hold a substrate (for example, a resist coated wafer) W and connected to a second positioner PW configured to accurately position the substrate W. Lithographic apparatus 100 and 100′ also have a projection system PS configured to project a pattern imparted to the radiation beam B by patterning device MA onto a target portion (for example, comprising one or more dies) C of the substrate W. In lithographic apparatus 100, the patterning device MA and the projection system PS are reflective. In lithographic apparatus 100′, the patterning device MA and the projection system PS are transmissive.

The illumination system IL can include various types of optical components, such as refractive, reflective, catadioptric, magnetic, electromagnetic, electrostatic, or other types of optical components, or any combination thereof, for directing, shaping, or controlling the radiation beam B.

The support structure MT holds the patterning device MA in a manner that depends on the orientation of the patterning device MA with respect to a reference frame, the design of at least one of the lithographic apparatus 100 and 100′, and other conditions, such as whether or not the patterning device MA is held in a vacuum environment. The support structure MT can use mechanical, vacuum, electrostatic, or other clamping techniques to hold the patterning device MA. The support structure MT can be a frame or a table, for example, which can be fixed or movable. By using sensors, the support structure MT can ensure that the patterning device MA is at a desired position, for example, with respect to the projection system PS.

The term “patterning device” MA should be broadly interpreted as referring to any device that can be used to impart a radiation beam B with a pattern in its cross-section, such as to create a pattern in the target portion C of the substrate W. The pattern imparted to the radiation beam B can correspond to a particular functional layer in a device being created in the target portion C to form an integrated circuit.

The patterning device MA can be transmissive (as in lithographic apparatus 100′ of FIG. 1B) or reflective (as in lithographic apparatus 100 of FIG. 1A). Examples of patterning devices MA include reticles, masks, programmable mirror arrays, or programmable LCD panels. Masks are well known in lithography, and include mask types such as binary, alternating phase shift, or attenuated phase shift, as well as various hybrid mask types. An example of a programmable mirror array employs a matrix arrangement of small mirrors, each of which can be individually tilted so as to reflect an incoming radiation beam in different directions. The tilted mirrors impart a pattern in the radiation beam B, which is reflected by a matrix of small mirrors.

The term “projection system” PS can encompass any type of projection system, including refractive, reflective, catadioptric, magnetic, electromagnetic and electrostatic optical systems, or any combination thereof, as appropriate for the exposure radiation being used, or for other factors, such as the use of an immersion liquid on the substrate W or the use of a vacuum. A vacuum environment can be used for EUV or electron beam radiation since other gases can absorb too much radiation or electrons. A vacuum environment can therefore be provided to the whole beam path with the aid of a vacuum wall and vacuum pumps.

Lithographic apparatus 100 and/or lithographic apparatus 100′ can be of a type having two (dual stage) or more substrate tables WT (and/or two or more mask tables). In such “multiple stage” machines, the additional substrate tables WT can be used in parallel, or preparatory steps can be carried out on one or more tables while one or more other substrate tables WT are being used for exposure. In some situations, the additional table may not be a substrate table WT.

The lithographic apparatus can also be of a type wherein at least a portion of the substrate can be covered by a liquid having a relatively high refractive index, e.g., water, so as to fill a space between the projection system and the substrate. An immersion liquid can also be applied to other spaces in the lithographic apparatus, for example, between the mask and the projection system. Immersion techniques are well known in the art for increasing the numerical aperture of projection systems. The term “immersion” as used herein does not mean that a structure, such as a substrate, must be submerged in liquid. For example, a liquid can be located between the projection system and the substrate during exposure.

Referring to FIGS. 1A and 1B, the illuminator IL receives a radiation beam from a radiation source SO. The source SO and the lithographic apparatus 100, 100′ can be separate physical entities, for example, when the source SO is an excimer laser. In such cases, the source SO is not considered to form part of the lithographic apparatus 100 or 100′, and the radiation beam B passes from the source SO to the illuminator IL with the aid of a beam delivery system BD (in FIG. 1B) including, for example, suitable directing mirrors and/or a beam expander. In other cases, the source SO can be an integral part of the lithographic apparatus 100, 100′, for example, when the source SO is a mercury lamp. A radiation system can comprise the source SO, the illuminator IL, and/or the beam delivery system BD.

The illuminator IL can include an adjuster AD (in FIG. 1B) for adjusting the angular intensity distribution of the radiation beam. Generally, at least the outer and/or inner radial extent (commonly referred to as “σ-outer” and “σ-inner,” respectively) of the intensity distribution in a pupil plane of the illuminator can be adjusted. In addition, the illuminator IL can comprise various other components (in FIG. 1B), such as an integrator IN and a condenser CO. The illuminator IL can be used to condition the radiation beam B to have a desired uniformity and intensity distribution in its cross section.

Referring to FIG. 1A, the radiation beam B is incident on the patterning device (for example, mask) MA, which is held on the support structure (for example, mask table) MT, and is patterned by the patterning device MA. In lithographic apparatus 100, the radiation beam B is reflected from the patterning device (for example, mask) MA. After being reflected from the patterning device (for example, mask) MA, the radiation beam B passes through the projection system PS, which focuses the radiation beam B onto a target portion C of the substrate W. With the aid of the second positioner PW and position sensor IF2 (for example, an interferometric device, linear encoder, or capacitive sensor), the substrate table WT can be moved accurately (for example, so as to position different target portions C in the path of the radiation beam B). Similarly, the first positioner PM and another position sensor IF1 can be used to accurately position the patterning device (for example, mask) MA with respect to the path of the radiation beam B. Patterning device (for example, mask) MA and substrate W can be aligned using mask alignment marks M1, M2 and substrate alignment marks P1, P2.

Referring to FIG. 1B, the radiation beam B is incident on the patterning device (for example, mask MA), which is held on the support structure (for example, mask table MT), and is patterned by the patterning device. Having traversed the mask MA, the radiation beam B passes through the projection system PS, which focuses the beam onto a target portion C of the substrate W. The projection system has a pupil conjugate PPU to an illumination system pupil IPU. Portions of radiation emanate from the intensity distribution at the illumination system pupil IPU and traverse a mask pattern without being affected by diffraction at the mask pattern and create an image of the intensity distribution at the illumination system pupil IPU.

The projection system PS projects an image of the mask pattern MP, where the image is formed by diffracted beams produced from the mask pattern MP by radiation from the intensity distribution, onto a photoresist layer coated on the substrate W. For example, the mask pattern MP can include an array of lines and spaces. A diffraction of radiation at the array and different from zeroth order diffraction generates diverted diffracted beams with a change of direction in a direction perpendicular to the lines. Undiffracted beams (i.e., so-called zeroth order diffracted beams) traverse the pattern without any change in propagation direction. The zeroth order diffracted beams traverse an upper lens or upper lens group of the projection system PS, upstream of the pupil conjugate PPU of the projection system PS, to reach the pupil conjugate PPU. The portion of the intensity distribution in the plane of the pupil conjugate PPU and associated with the zeroth order diffracted beams is an image of the intensity distribution in the illumination system pupil IPU of the illumination system IL. The aperture device PD, for example, is disposed at or substantially at a plane that includes the pupil conjugate PPU of the projection system PS.

The projection system PS is arranged to capture (e.g., using a lens or lens group L) the zeroth order diffracted beams, first order diffracted beams, and/or higher order diffracted beams (not shown). In some aspects, dipole illumination for imaging line patterns extending in a direction perpendicular to a line can be used to utilize the resolution enhancement effect of dipole illumination. For example, first-order diffracted beams interfere with corresponding zeroth-order diffracted beams at the level of the wafer W to create an image of the line pattern MP at highest possible resolution and process window (i.e., usable depth of focus in combination with tolerable exposure dose deviations). In some aspects, astigmatism aberration can be reduced by providing radiation poles (not shown) in opposite quadrants of the illumination system pupil IPU. Further, in some aspects, astigmatism aberration can be reduced by blocking the zeroth order beams in the pupil conjugate PPU of the projection system associated with radiation poles in opposite quadrants. This is described in more detail in U.S. Pat. No. 7,511,799 B2, issued Mar. 31, 2009, which is incorporated by reference herein in its entirety.

With the aid of the second positioner PW and position sensor IFD (for example, an interferometric device, linear encoder, or capacitive sensor), the substrate table WT can be moved accurately (for example, so as to position different target portions C in the path of the radiation beam B). Similarly, the first positioner PM and another position sensor (not shown in FIG. 1B) can be used to accurately position the mask MA with respect to the path of the radiation beam B (for example, after mechanical retrieval from a mask library or during a scan).

In general, movement of the mask table MT can be realized with the aid of a long-stroke module (coarse positioning) and a short-stroke module (fine positioning), which form part of the first positioner PM. Similarly, movement of the substrate table WT can be realized using a long-stroke module and a short-stroke module, which form part of the second positioner PW. In the case of a stepper (as opposed to a scanner), the mask table MT can be connected to a short-stroke actuator or can be fixed. Mask MA and substrate W can be aligned using mask alignment marks M1, M2, and substrate alignment marks P1, P2. Although the substrate alignment marks (as illustrated) occupy dedicated target portions, they can be located in spaces between target portions (known as scribe-lane alignment marks). Similarly, in situations in which more than one die is provided on the mask MA, the mask alignment marks can be located between the dies.

Mask table MT and patterning device MA can be in a vacuum chamber V, where an in-vacuum robot IVR can be used to move patterning devices such as a mask in and out of vacuum chamber. Alternatively, when mask table MT and patterning device MA are outside of the vacuum chamber, an out-of-vacuum robot can be used for various transportation operations, similar to the in-vacuum robot IVR. Both the in-vacuum and out-of-vacuum robots can be calibrated for a smooth transfer of any payload (e.g., mask) to a fixed kinematic mount of a transfer station.

The lithographic apparatus 100 and 100′ can be used in at least one of the following modes:
1. In step mode, the support structure (for example, mask table) MT and the substrate table WT are kept essentially stationary, while an entire pattern imparted to the radiation beam B is projected onto a target portion C at one time (i.e., a single static exposure). The substrate table WT is then shifted in the X and/or Y direction so that a different target portion C can be exposed.
2. In scan mode, the support structure (for example, mask table) MT and the substrate table WT are scanned synchronously while a pattern imparted to the radiation beam B is projected onto a target portion C (i.e., a single dynamic exposure). The velocity and direction of the substrate table WT relative to the support structure (for example, mask table) MT can be determined by the (de-) magnification and image reversal characteristics of the projection system PS.
3. In another mode, the support structure (for example, mask table) MT is kept substantially stationary holding a programmable patterning device, and the substrate table WT is moved or scanned while a pattern imparted to the radiation beam B is projected onto a target portion C. A pulsed radiation source SO can be employed and the programmable patterning device is updated as needed after each movement of the substrate table WT or in between successive radiation pulses during a scan. This mode of operation can be readily applied to maskless lithography that utilizes a programmable patterning device, such as a programmable mirror array.

Combinations and/or variations on the described modes of use or entirely different modes of use can also be employed.

In some aspects, lithographic apparatus 100 includes an extreme ultraviolet (EUV) source, which is configured to generate a beam of EUV radiation for EUV lithography. In general, the EUV source is configured in a radiation system, and a corresponding illumination system is configured to condition the EUV radiation beam of the EUV source.

In some aspects, lithographic apparatus 100′ includes a deep ultraviolet (DUV) source, which is configured to generate a beam of DUV radiation for DUV lithography. In general, the DUV source is configured in a radiation system, and a corresponding illumination system is configured to condition the DUV radiation beam of the DUV source.

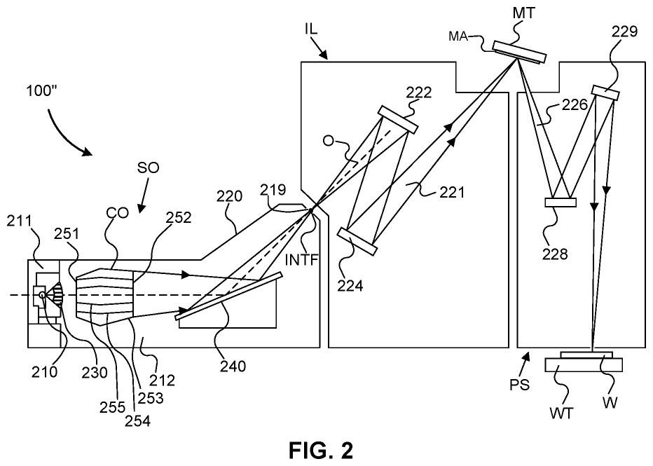

FIG. 2 shows the lithographic apparatus 100 in more detail, including the source collector apparatus SO, the illumination system IL, and the projection system PS. The source collector apparatus SO is constructed and arranged such that a vacuum environment can be maintained in an enclosing structure 220 of the source collector apparatus SO. An EUV radiation emitting plasma 210 can be formed by a discharge produced plasma source. In some aspects, a plasma of excited tin (Sn) (e.g., excited via a laser) is provided to produce EUV radiation.

The radiation emitted by the EUV radiation emitting plasma 210 is passed from a source chamber 211 into a collector chamber 212 via an optional gas barrier or contaminant trap 230 (in some cases also referred to as contaminant barrier or foil trap), which is positioned in or behind an opening in source chamber 211. The contaminant trap 230 can include a channel structure. Contamination trap 230 can also include a gas barrier or a combination of a gas barrier and a channel structure. The contaminant trap or contaminant barrier 230 further indicated herein at least includes a channel structure.

The collector chamber 212 can include a radiation collector CO, which can be a so-called grazing incidence collector. Radiation collector CO has an upstream radiation collector side 251 and a downstream radiation collector side 252. Radiation that traverses collector CO can be reflected off a grating spectral filter 240 to be focused in a virtual source point INTF. The virtual source point INTF is commonly referred to as the intermediate focus, and the source collector apparatus is arranged such that the intermediate focus INTF is located at or near an opening 219 in the enclosing structure 220. The virtual source point INTF is an image of the EUV radiation emitting plasma 210. Grating spectral filter 240 is used in particular for suppressing infra-red (IR) radiation.

Subsequently the radiation traverses the illumination system IL, which can include a faceted field mirror device 222 and a faceted pupil mirror device 224 arranged to provide a desired angular distribution of the radiation beam 221, at the patterning device MA, as well as a desired uniformity of radiation intensity at the patterning device MA. Upon reflection of the beam of radiation 221 at the patterning device MA, held by the support structure MT, a patterned beam 226 is formed and the patterned beam 226 is imaged by the projection system PS via reflective elements 228, 229 onto a substrate W held by the wafer stage or substrate table WT.

More elements than shown can generally be present in illumination optics unit IL and projection system PS. The grating spectral filter 240 can optionally be present, depending upon the type of lithographic apparatus. Further, there can be more mirrors present than those shown in the FIG. 2, for example there can be one to six additional reflective elements present in the projection system PS than shown in FIG. 2.

Collector optic CO, as illustrated in FIG. 2, is depicted as a nested collector with grazing incidence reflectors 253, 254, and 255, just as an example of a collector (or collector mirror). The grazing incidence reflectors 253, 254, and 255 are disposed axially symmetric around an optical axis O and a collector optic CO of this type is preferably used in combination with a discharge produced plasma source, often called a DPP source.

### Example Lithographic Cell

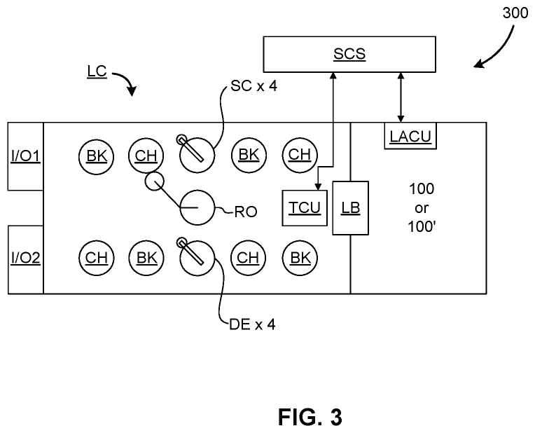

FIG. 3 shows a lithographic cell 300, also sometimes referred to a lithocell or cluster, according to some aspects. Lithographic apparatus 100 or 100′ can form part of lithographic cell 300. Lithographic cell 300 can also include one or more apparatuses to perform pre- and post-exposure processes on a substrate. Conventionally these include spin coaters SC to deposit resist layers, developers DE to develop exposed resist, chill plates CH, and bake plates BK. A substrate handler, or robot, RO picks up substrates from input/output ports I/O1, I/O2, moves them between the different process apparatuses and delivers them to the loading bay LB of the lithographic apparatus 100 or 100′. These devices, which are often collectively referred to as the track, are under the control of a track control unit TCU, which is itself controlled by a supervisory control system SCS, which also controls the lithographic apparatus via lithography control unit LACU. Thus, the different apparatuses can be operated to maximize throughput and processing efficiency.

### Example Inspection Apparatus

In order to control the lithographic process to place device features accurately on the substrate, alignment marks are generally provided on the substrate, and the lithographic apparatus includes one or more inspection apparatuses for accurate positioning of marks on a substrate. These alignment apparatuses are effectively position measuring apparatuses. Different types of marks and different types of alignment apparatuses and/or systems are known from different times and different manufacturers. A type of system widely used in current lithographic apparatus is based on a self-referencing interferometer as described in U.S. Pat. No. 6,961,116 (den Boef et al.). Generally marks are measured separately to obtain X- and Y-positions. A combined X- and Y-measurement can be performed using the techniques described in U.S. Publication No. 2009/195768 A (Bijnen et al.), however. The full contents of both of these disclosures are incorporated herein by reference.

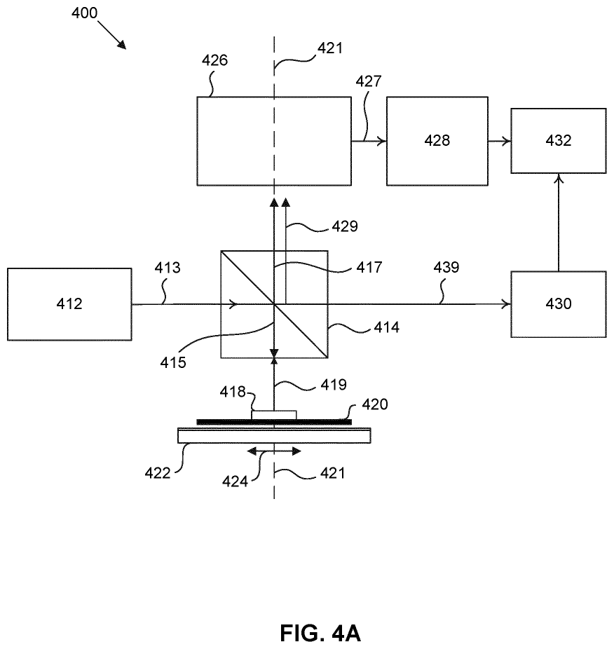

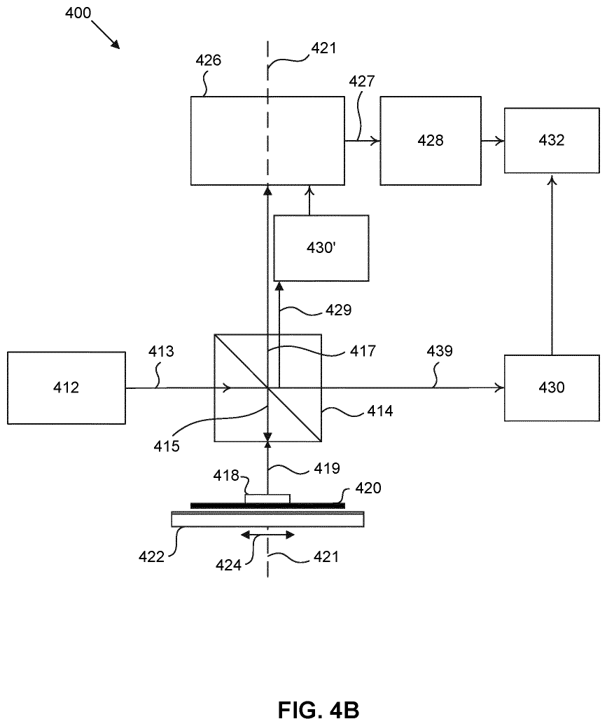

FIG. 4A shows a cross-sectional view of an inspection apparatus 400 that can be implemented as a part of lithographic apparatus 100 or 100′, according to some aspects. In some aspects, inspection apparatus 400 can be configured to align a substrate (e.g., substrate W) with respect to a patterning device (e.g., patterning device MA). Inspection apparatus 400 can be further configured to detect positions of alignment marks on the substrate and to align the substrate with respect to the patterning device or other components of lithographic apparatus 100 or 100′ using the detected positions of the alignment marks. Such alignment of the substrate can ensure accurate exposure of one or more patterns on the substrate.

The terms “inspection apparatus,” “metrology system,” or the like can be used herein to refer to, e.g., a device used for measuring a property of a structure (e.g., overlay sensor, critical dimension sensor, or the like), a device or system used in a lithographic apparatus to inspect an alignment of a wafer (e.g., alignment sensor), or the like.

In some aspects, inspection apparatus 400 can include an illumination system 412, a beam splitter 414, an interferometer 426, a detector 428, a beam analyzer 430, and an overlay calculation processor 432. Illumination system 412 can be configured to provide an electromagnetic narrow band radiation beam 413 having one or more passbands. In an example, the one or more passbands can be within a spectrum of wavelengths between about 500 nm to about 900 nm. In another example, the one or more passbands can be discrete narrow passbands within a spectrum of wavelengths between about 500 nm to about 900 nm. Illumination system 412 can be further configured to provide one or more passbands having substantially constant center wavelength (CWL) values over a long period of time (e.g., over a lifetime of illumination system 412). Such configuration of illumination system 412 can help to prevent the shift of the actual CWL values from the desired CWL values, as discussed above, in current alignment systems. And, as a result, the use of constant CWL values can improve long-term stability and accuracy of alignment systems (e.g., inspection apparatus 400) compared to the current alignment apparatuses.

In some aspects, beam splitter 414 can be configured to receive radiation beam 413 and split radiation beam 413 into at least two radiation sub-beams. For example, radiation beam 413 can be split into radiation sub-beams 415 and 417, as shown in FIG. 4A. Beam splitter 414 can be further configured to direct radiation sub-beam 415 onto a substrate 420 placed on a stage 422. In one example, the stage 422 is movable along direction 424. Radiation sub-beam 415 can be configured to illuminate an alignment mark or a target 418 located on substrate 420. Alignment mark or target 418 can be coated with a radiation sensitive film. In some aspects, alignment mark or target 418 can have one hundred and eighty degrees (i.e., 180°) symmetry. That is, when alignment mark or target 418 is rotated 180° about an axis of symmetry perpendicular to a plane of alignment mark or target 418, rotated alignment mark or target 418 can be substantially identical to an unrotated alignment mark or target 418. The target 418 on substrate 420 can be (a) a resist layer grating comprising bars that are formed of solid resist lines, or (b) a product layer grating, or (c) a composite grating stack in an overlay target structure comprising a resist grating overlaid or interleaved on a product layer grating. The bars can alternatively be etched into the substrate. This pattern is sensitive to chromatic aberrations in the lithographic projection apparatus, particularly the projection system PL, and illumination symmetry and the presence of such aberrations will manifest themselves in a variation in the printed grating. One in-line method used in device manufacturing for measurements of line width, pitch, and critical dimension makes use of a technique known as “scatterometry”. Methods of scatterometry are described in Raymond et al., “Multiparameter Grating Metrology Using Optical Scatterometry”, J. Vac. Sci. Tech. B, Vol. 15, no. 2, pp. 361-368 (1997) and Niu et al., “Specular Spectroscopic Scatterometry in DUV Lithography”, SPIE, Vol. 3677 (1999), which are both incorporated by reference herein in their entireties. In scatterometry, light is reflected by periodic structures in the target, and the resulting reflection spectrum at a given angle is detected. The structure giving rise to the reflection spectrum is reconstructed, e.g. using Rigorous Coupled-Wave Analysis (RCWA) or by comparison to a library of patterns derived by simulation. Accordingly, the scatterometry data of the printed gratings is used to reconstruct the gratings. The parameters of the grating, such as line widths and shapes, can be input to the reconstruction process, performed by processing unit PU, from knowledge of the printing step and/or other scatterometry processes.

In some aspects, beam splitter 414 can be further configured to receive diffraction radiation beam 419 and split diffraction radiation beam 419 into at least two radiation sub-beams, according to an aspect. Diffraction radiation beam 419 can be split into diffraction radiation sub-beams 429 and 439, as shown in FIG. 4A.

It should be noted that even though beam splitter 414 is shown to direct radiation sub-beam 415 towards alignment mark or target 418 and to direct diffracted radiation sub-beam 429 towards interferometer 426, the disclosure is not so limiting. Other optical arrangements can be used to obtain the similar result of illuminating alignment mark or target 418 on substrate 420 and detecting an image of alignment mark or target 418.

As illustrated in FIG. 4A, interferometer 426 can be configured to receive radiation sub-beam 417 and diffracted radiation sub-beam 429 through beam splitter 414. In an example aspect, diffracted radiation sub-beam 429 can be at least a portion of radiation sub-beam 415 that can be reflected from alignment mark or target 418. In an example of this aspect, interferometer 426 comprises any appropriate set of optical-elements, for example, a combination of prisms that can be configured to form two images of alignment mark or target 418 based on the received diffracted radiation sub-beam 429. It should be appreciated that a good quality image need not be formed. It can be enough to have the features of alignment mark 418 resolved. Interferometer 426 can be further configured to rotate one of the two images with respect to the other of the two images 180° and recombine the rotated and unrotated images interferometrically.

In some aspects, detector 428 can be configured to receive the recombined image via interferometer signal 427 and detect interference as a result of the recombined image when alignment axis 421 of inspection apparatus 400 passes through a center of symmetry (not shown) of alignment mark or target 418. Such interference can be due to alignment mark or target 418 being 180° symmetrical, and the recombined image interfering constructively or destructively, according to an example aspect. Based on the detected interference, detector 428 can be further configured to determine a position of the center of symmetry of alignment mark or target 418 and consequently, detect a position of substrate 420. According to an example, alignment axis 421 can be aligned with an optical beam perpendicular to substrate 420 and passing through a center of image rotation interferometer 426. Detector 428 can be further configured to estimate the positions of alignment mark or target 418 by implementing sensor characteristics and interacting with wafer mark process variations.

In a further aspect, detector 428 determines the position of the center of symmetry of alignment mark or target 418 by performing one or more of the following measurements:
1. measuring position variations for various wavelengths (position shift between colors);
2. measuring position variations for various orders (position shift between diffraction orders); and
3. measuring position variations for various polarizations (position shift between polarizations).

This data can be obtained using any type of alignment sensor, for example, a SMASH (SMart Alignment Sensor Hybrid) sensor, as described in U.S. Pat. No. 6,961,116 that employs a self-referencing interferometer with a single detector and four different wavelengths, and extracts the alignment signal in software, or Athena (Advanced Technology using High order ENhancement of Alignment), as described in U.S. Pat. No. 6,297,876, which directs each of seven diffraction orders to a dedicated detector, which are both incorporated by reference herein in their entireties.

In some aspects, beam analyzer 430 can be configured to receive and determine an optical state of diffracted radiation sub-beam 439. The optical state can be a measure of beam wavelength, polarization, or beam profile. Beam analyzer 430 can be further configured to determine a position of stage 422 and correlate the position of stage 422 with the position of the center of symmetry of alignment mark or target 418. As such, the position of alignment mark or target 418 and, consequently, the position of substrate 420 can be accurately known with reference to stage 422. Alternatively, beam analyzer 430 can be configured to determine a position of inspection apparatus 400 or any other reference element such that the center of symmetry of alignment mark or target 418 can be known with reference to inspection apparatus 400 or any other reference element. Beam analyzer 430 can be a point or an imaging polarimeter with some form of wavelength-band selectivity. In some aspects, beam analyzer 430 can be directly integrated into inspection apparatus 400, or connected via fiber optics of several types: polarization preserving single mode, multimode, or imaging, according to other aspects.

In some aspects, beam analyzer 430 can be further configured to determine the overlay data between two patterns on substrate 420. One of these patterns can be a reference pattern on a reference layer. The other pattern can be an exposed pattern on an exposed layer. The reference layer can be an etched layer already present on substrate 420. The reference layer can be generated by a reference pattern exposed on the substrate by lithographic apparatus 100 and/or 100′. The exposed layer can be a resist layer exposed adjacent to the reference layer. The exposed layer can be generated by an exposure pattern exposed on substrate 420 by lithographic apparatus 100 or 100′. The exposed pattern on substrate 420 can correspond to a movement of substrate 420 by stage 422. In some aspects, the measured overlay data can also indicate an offset between the reference pattern and the exposure pattern. The measured overlay data can be used as calibration data to calibrate the exposure pattern exposed by lithographic apparatus 100 or 100′, such that after the calibration, the offset between the exposed layer and the reference layer can be minimized.

In some aspects, beam analyzer 430 can be further configured to determine a model of the product stack profile of substrate 420, and can be configured to measure overlay, critical dimension, and focus of target 418 in a single measurement. The product stack profile contains information on the stacked product such as alignment mark, target 418, or substrate 420, and can include mark process variation-induced optical signature metrology that is a function of illumination variation. The product stack profile can also include product grating profile, mark stack profile, and mark asymmetry information. An example of beam analyzer 430 is Yieldstar™, manufactured by ASML, Veldhoven, The Netherlands, as described in U.S. Pat. No. 8,706,442, which is incorporated by reference herein in its entirety. Beam analyzer 430 can be further configured to process information related to a particular property of an exposed pattern in that layer. For example, beam analyzer 430 can process an overlay parameter (an indication of the positioning accuracy of the layer with respect to a previous layer on the substrate or the positioning accuracy of the first layer with respective to marks on the substrate), a focus parameter, and/or a critical dimension parameter (e.g., line width and its variations) of the depicted image in the layer. Other parameters are image parameters relating to the quality of the depicted image of the exposed pattern.

In some aspects, an array of detectors (not shown) can be connected to beam analyzer 430, and allows the possibility of accurate stack profile detection as discussed below. For example, detector 428 can be an array of detectors. For the detector array, a number of options are possible: a bundle of multimode fibers, discrete pin detectors per channel, or CCD or CMOS (linear) arrays. The use of a bundle of multimode fibers enables any dissipating elements to be remotely located for stability reasons. Discrete PIN detectors offer a large dynamic range but each need separate pre-amps. The number of elements is therefore limited. CCD linear arrays offer many elements that can be read-out at high speed and are especially of interest if phase-stepping detection is used.

In some aspects, a second beam analyzer 430′ can be configured to receive and determine an optical state of diffracted radiation sub-beam 429, as shown in FIG. 4B. The optical state can be a measure of beam amplitude and phase, beam wavelength, polarization, or beam profile. Second beam analyzer 430′ can be identical to beam analyzer 430. Alternatively, second beam analyzer 430′ can be configured to perform one or more of the functions of beam analyzer 430, such as determining a position of stage 422 and correlating the position of stage 422 with the position of the center of symmetry of alignment mark or target 418. As such, the position of alignment mark or target 418 and, consequently, the position of substrate 420, can be accurately known with reference to stage 422. Second beam analyzer 430′ can also be configured to determine a position of inspection apparatus 400, or any other reference element, such that the center of symmetry of alignment mark or target 418 can be known with reference to inspection apparatus 400, or any other reference element. Second beam analyzer 430′ can be further configured to determine the overlay data between two patterns and a model of the product stack profile of substrate 420. Second beam analyzer 430′ can also be configured to measure overlay, critical dimension, and focus of target 418 in a single measurement.

In some aspects, second beam analyzer 430′ can be directly integrated into inspection apparatus 400, or it can be connected via fiber optics of several types: polarization preserving single mode, multimode, or imaging, according to other aspects. Alternatively, second beam analyzer 430′ and beam analyzer 430 can be combined to form a single analyzer (not shown) configured to receive and determine the optical states of both diffracted radiation sub-beams 429 and 439.

In some aspects, processor 432 receives information from detector 428 and beam analyzer 430. For example, processor 432 can be an overlay calculation processor. The information can comprise a model of the product stack profile constructed by beam analyzer 430. Alternatively, processor 432 can construct a model of the product mark profile using the received information about the product mark. In either case, processor 432 constructs a model of the stacked product and overlay mark profile using or incorporating a model of the product mark profile. The stack model is then used to determine the overlay offset and minimizes the spectral effect on the overlay offset measurement. Processor 432 can create a basic correction algorithm based on the information received from detector 428 and beam analyzer 430, including but not limited to the optical state of the illumination beam, the alignment signals, associated position estimates, and the optical state in the pupil, image, and additional planes. The pupil plane is the plane in which the radial position of radiation defines the angle of incidence and the angular position defines the azimuth angle of the radiation. Processor 432 can utilize the basic correction algorithm to characterize the inspection apparatus 400 with reference to wafer marks and/or alignment marks 418.

In some aspects, processor 432 can be further configured to determine printed pattern position offset error with respect to the sensor estimate for each mark based on the information received from detector 428 and beam analyzer 430. The information includes but is not limited to the product stack profile, measurements of overlay, critical dimension, and focus of each alignment marks or target 418 on substrate 420. Processor 432 can utilize a clustering algorithm to group the marks into sets of similar constant offset error, and create an alignment error offset correction table based on the information. The clustering algorithm can be based on overlay measurement, the position estimates, and additional optical stack process information associated with each set of offset errors. The overlay is calculated for a number of different marks, for example, overlay targets having a positive and a negative bias around a programmed overlay offset. The target that measures the smallest overlay is taken as reference (as it is measured with the best accuracy). From this measured small overlay, and the known programmed overlay of its corresponding target, the overlay error can be deduced. Table 1 illustrates how this can be performed. The smallest measured overlay in the example shown is −1 nm. However this is in relation to a target with a programmed overlay of −30 nm. The process may have introduced an overlay error of 29 nm.

TABLE 1

| | | | | | | | |
|---|---|---|---|---|---|---|---|
| Programmed overlay | −70 | −50 | −30 | −10 | 10 | 30 | 50 |
| Measured overlay | −38 | −19 | −1 | 21 | 43 | 66 | 90 |
| Difference between | 32 | 31 | 29 | 31 | 33 | 36 | 40 |
| measured and | | | | | | | |
| programmed overlay | | | | | | | |
| Overlay error | 3 | 2 | — | 2 | 4 | 7 | 11 |

The smallest value can be taken to be the reference point and, relative to this, the offset can be calculated between measured overlay and that expected due to the programmed overlay. This offset determines the overlay error for each mark or the sets of marks with similar offsets. Therefore, in the Table 1 example, the smallest measured overlay was −1 nm, at the target position with programmed overlay of 30 nm. The difference between the expected and measured overlay at the other targets is compared to this reference. A table such as Table 1 can also be obtained from marks and target 418 under different illumination settings, the illumination setting, which results in the smallest overlay error, and its corresponding calibration factor, can be determined and selected. Following this, processor 432 can group marks into sets of similar overlay error. The criteria for grouping marks can be adjusted based on different process controls, for example, different error tolerances for different processes.

In some aspects, processor 432 can confirm that all or most members of the group have similar offset errors, and apply an individual offset correction from the clustering algorithm to each mark, based on its additional optical stack metrology. Processor 432 can determine corrections for each mark and feed the corrections back to lithographic apparatus 100 or 100′ for correcting errors in the overlay, for example, by feeding corrections into the inspection apparatus 400.

### Exemplary Topology Optimized Alignment Marks

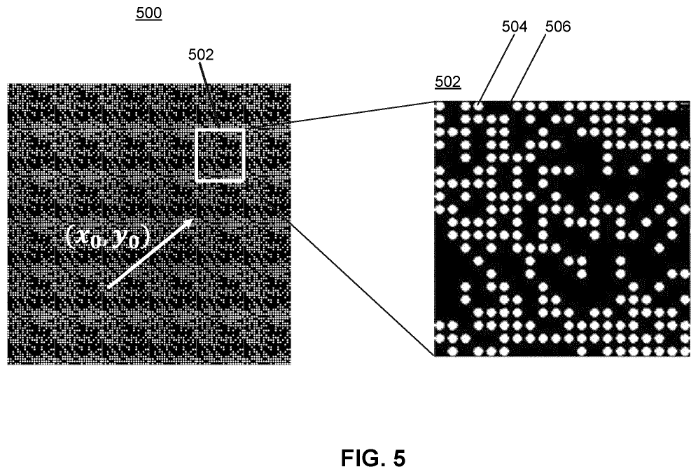

FIG. 5 schematically represents a topology optimized alignment mark that can be designed using an inverse design method according to some embodiments. As shown in FIG. 5, an alignment mark 500 according to some embodiments may be comprised of a plurality of unit cells 502 (shown enlarged on the right of FIG. 5). FIG. 5 shows a unit cell 502 of alignment mark 500 divided into white individual pixels 504 and black individual pixels 506. Different pixels 504, 506 may be formed of materials having different properties (e.g., refractive indices, materials, etch depth, or the like), and thus the pixels 504, 506 will constitute a topology of the alignment mark 500. In some embodiments, pixels 504, 506 may be divided into two groups, a first group formed of a first material having a first property (e.g., a first index of refraction) and a second group formed of a second material having a second property (e.g., a second index of refraction). However, the invention is not limited to using only two materials with different properties, but encompasses the use of three or more materials with different properties. In some aspects, the choices of materials may be arbitrary so long as the materials have suitably different properties. On the other hand, the materials may be chosen to have properties optimized based on one more characteristics of the materials forming the pixels, the wafer being processed, the radiation used by the alignment system, or any other aspect of the lithography system.

In some embodiments, alignment mark 500 may be processed by using a metrology system to scan the alignment mark along a given direction. In some aspects, scanning of alignment mark 500 may be represented by a translation along the x-direction and/or the y-direction, as shown in FIG. 5 by the scanning function (x₀,y₀).

The following description of an inverse design method for topology optimized alignment marks will be provided with regard to an alignment mark comprising two materials of different refractive indices. However, it is noted that this description could be generalized to an alignment mark having n different materials, or an alignment mark comprised of materials constituting n different refractive indices, where n is any integer, or a plurality of materials having varying etch depths, such that the materials form any fraction of a pixel between 0 and 1.

According to some embodiments, alignment mark 500 may be divided into at least two pixels 504, 506 made from different materials (e.g., a light pixel 504 and a dark pixel 506). In some aspects, the diffraction efficiency of such an alignment mark can be modeled. In practice, the particular choice of materials may have some influence on the diffraction efficiency of the alignment mark 500. In some aspects, by using a shallow grating approximation, the far-field radiation pattern of the alignment mark 500 will be independent of the choice of materials (or the etch depth of the materials), and thus the diffraction efficiency can be approximated by considering only the far-field radiation pattern of the alignment mark 500. In other aspects, if full-wave vectorial simulation is done, the mark material, the substrate and the layers above and beneath the mark also play a role on the far-field radiation pattern.

In some aspects, a shallow grating approximation for the far-field radiation pattern for an alignment mark 500 comprising materials with two different refractive indices may be expressed as follows:

$$ϕ ( {θ}_{x} , {θ}_{y} ) = ℱ \{ {E}_{in} ( {x}_{0} , {y}_{0} , x , y ) G ( {x}_{m} , {y}_{n} ) \} ,$$

where φ (θₓ, θ_{y}) is the far-field pattern for radiation angles of θₓ and θ_{y}, Eᵢₙ is the electric field incident on the alignment mark, (x₀,y₀) represents the center of the beam of incident radiation, G(xₘ, yₙ) is a function particular to the design of the alignment mark, and [symbol] is the Fourier transform. Because Eᵢₙ is a function of (x₀,y₀,x,y), the electric field distribution in the x- and y-directions changes along a scanning direction of the alignment mark. G(xₘ,yₙ) adds a phase to the electric field in each pixel, and may depend on a refractive index of the material of the pixel, the etch depth of the alignment mark, or the like.

In some aspects, although characteristics of the alignment mark 500 may affect the intensity of the electric field and the pattern of zeroth order diffraction from the alignment mark 500, using two materials having different refractive indices allows the pattern of the first order diffraction from the alignment mark to still be independent of material choice.

With the above general expression for a far-field radiation pattern for an alignment mark, it is possible to develop an optimization framework for any proposed alignment mark. In some aspects, such an optimization framework may be developed by defining a cost function. According to some embodiments, a cost function based on the above general expression for a far-field pattern may be defined as:

$$F ( ϕ ( {θ}_{x} , {θ}_{y} ) , ε ( {x}_{m} , {y}_{n} ) , [ {x}_{0} , {y}_{0} = α {x}_{0} + β ] ) ,$$

where F is the cost function, ε is the permittivity of either of the two materials, and y₀=αx₀+β is a scanning function as shown in FIG. 5. Other functions may also be included in the cost function. For example, for some sensors, a self-referencing interferometer (SRI) transfer function may be included, whereas for image-based sensors, a different transfer function may be used.

In some aspects, the cost function may define the sensitivity of the radiation pattern to the scanning function, to one or more of the KPIs discussed above (such as, for example, 6DOF), to an alignment mark asymmetry, or the like. In some aspects, it may be desirable for the cost function to be insensitive to polarization, alignment mark symmetry, tilt, defocus, or the like.

In some embodiments, an optimal topology for an alignment mark can be identified by minimizing a cost function according to the above description. Thus, optimization goals may defined as one or more of the following conditions:

$$( \frac{\partial F}{\partial β} ) = 0 ; ( \frac{\partial F}{\partial ε} ) = 0 ; ( \frac{\partial F}{\partial {ϕ}_{x , y}} ) = 0 ; ( \frac{\partial F}{\partial α} ) = 0.$$

One of ordinary skill in the art will appreciate that optimization goal(s) can vary depending on particular characteristics of the alignment mark or on the application for which the alignment mark is to be used.

An inverse design method for alignment marks may proceed, in some embodiments, by determining a far-field radiation pattern for a proposed alignment mark. Based on the far-field radiation pattern, a cost function may be developed for the proposed alignment mark. Then, a specific topology of the alignment mark may be tuned by minimizing the cost function to achieve one or more of the above optimization goals. This optimization will produce a set of values that may be used to form an alignment mark having an optimized topology. In other embodiments, alignment marks having an optimized topology may be automatically identified by optimizing a cost function along one or more parameters, as discussed above.

The above method is generalizable to any alignment mark, and thus constitutes a general framework for topology optimized alignment marks.

In some aspects, a pattern for an alignment mark includes a repeating unit cell of pixels (such as, e.g., unit cell 502 in FIG. 5), and the pixels 504, 506 of each unit cell form a pixel subpattern. In some embodiments, the pixel subpattern may repeat periodically or semi-periodically, or may not repeat within the unit cell such that the subpattern is non-periodic. The subpattern of the unit cell may be determined based on one or more optimization goals of the cost function, as described above. That is, once a subpattern for the unit cell is proposed, the subpattern may be tuned by determining the far-field diffraction pattern and corresponding cost function of the subpattern, and then optimizing the cost function, as described above.

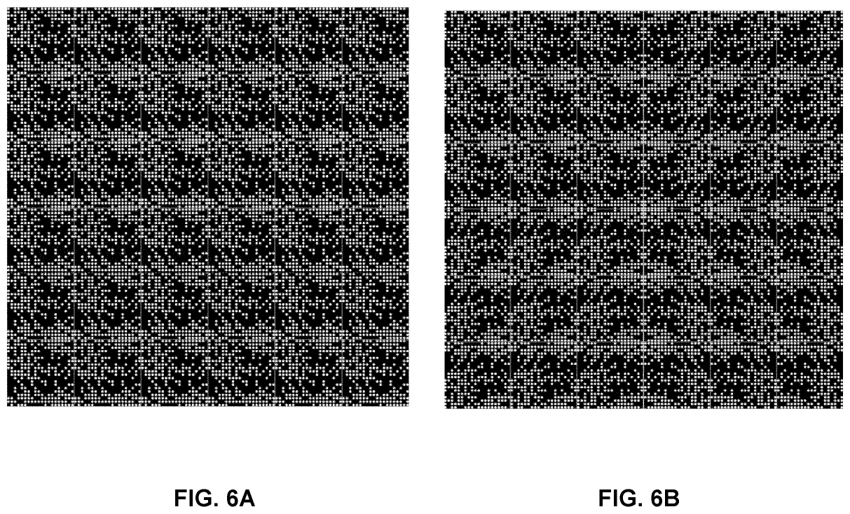

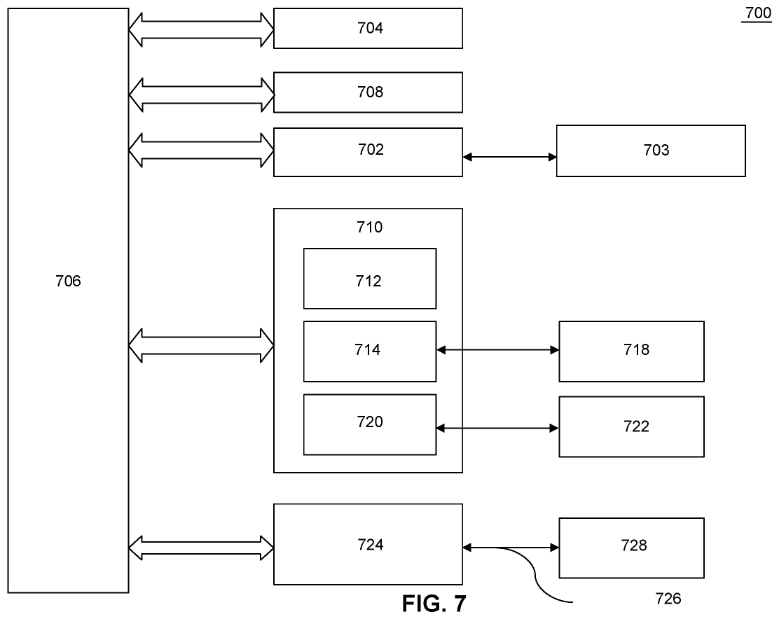

In addition to determining the subpattern for the unit cell, symmetry of the repeating unit cells may be determined. For example, as shown schematically in FIG. 6A, the unit cell of an alignment mark may repeat periodically, in which case the unit cell is translated across the alignment mark. As another example, FIG. 6B schematically shows an example where the unit cell of an alignment mark is disposed to form a centro-symmetric pattern, such that the unit cell is symmetric about the center of the alignment mark. One of ordinary skill in the art will appreciate that such unit cell symmetries are merely examples, and that other types of unit cell symmetries could readily be implemented, such as an inversion or rotational symmetry about a non-centric point of the alignment mark, a mirror symmetry, a combination of two or more of such symmetries, or the like. Here, again, the symmetry of the unit cell may be determined based on one or more optimization goals of the cost function, as described above.

Once a pattern of the alignment mark, including a subpattern of the pixels and a symmetry of the unit cell, is determined and optimized, the alignment mark may be formed on the device. For example, the alignment mark may be formed by depositing a first material and a second material. Alternatively, the alignment mark may be formed by removing a first material (e.g., by etching), to expose a second material. Other methods for forming an alignment mark will be immediately apparent to one of ordinary skill in the art, such as a combination of etching and deposition, an additive manufacturing, a nanolithography, or the like. The first and second materials may be similar but different materials such as, for example, different metal materials or different dielectric materials, or may be different materials such as, for example, a metal and a dielectric material.

Where more than two materials, or materials having more than two effective refractive indices, are used, any suitable process may be used to form the required number of materials into the alignment mark pattern.

According to some embodiments, minimization of a cost function allows for optimization of one or more KPIs of the optimized alignment mark. By comparing the results of different minimizations of the cost function, it is possible to find the optimum solution and fundamental limits of the cost function. In addition, costs and benefits can be compared between designs for the alignment mark, to determine the optimum pattern for the alignment mark.

### Computer Implementation of the Design Process

Various embodiments may be implemented, for example, using one or more well-known computer systems, such as computer system 700 shown in FIG. 7. For example, media device may be implemented using combinations or sub-combinations of computer system 700. Also or alternatively, one or more computer systems 700 may be used, for example, to implement any of the embodiments discussed herein, as well as combinations and sub-combinations thereof.

Computer system 700 may include one or more processors (also called central processing units, or CPUs), such as a processor 704. Processor 704 may be connected to a communication infrastructure or bus 706.

Computer system 700 may also include user input/output device(s) 703, such as monitors, keyboards, pointing devices, etc., which may communicate with communication infrastructure 706 through user input/output interface(s) 702.

One or more of processors 704 may be a graphics processing unit (GPU). In an embodiment, a GPU may be a processor that is a specialized electronic circuit designed to process mathematically intensive applications. The GPU may have a parallel structure that is efficient for parallel processing of large blocks of data, such as mathematically intensive data common to computer graphics applications, images, videos, etc.

Computer system 700 may also include a main or primary memory 708, such as random access memory (RAM). Main memory 708 may include one or more levels of cache. Main memory 708 may have stored therein control logic (i.e., computer software) and/or data.

Computer system 700 may also include one or more secondary storage devices or memory 710. Secondary memory 710 may include, for example, a hard disk drive 712 and/or a removable storage device or drive 714. Removable storage drive 714 may be a floppy disk drive, a magnetic tape drive, a compact disk drive, an optical storage device, tape backup device, and/or any other storage device/drive.

Removable storage drive 714 may interact with a removable storage unit 718. Removable storage unit 718 may include a computer usable or readable storage device having stored thereon computer software (control logic) and/or data. Removable storage unit 718 may be a floppy disk, magnetic tape, compact disk, DVD, optical storage disk, and/any other computer data storage device. Removable storage drive 714 may read from and/or write to removable storage unit 718.

Secondary memory 710 may include other means, devices, components, instrumentalities or other approaches for allowing computer programs and/or other instructions and/or data to be accessed by computer system 700. Such means, devices, components, instrumentalities or other approaches may include, for example, a removable storage unit 722 and an interface 720. Examples of the removable storage unit 722 and the interface 720 may include a program cartridge and cartridge interface (such as that found in video game devices), a removable memory chip (such as an EPROM or PROM) and associated socket, a memory stick and USB or other port, a memory card and associated memory card slot, and/or any other removable storage unit and associated interface.

Computer system 700 may further include a communication or network interface 724. Communication interface 724 may enable computer system 700 to communicate and interact with any combination of external devices, external networks, external entities, etc. (individually and collectively referenced by reference number 728). For example, communication interface 724 may allow computer system 700 to communicate with external or remote devices 728 over communications path 726, which may be wired and/or wireless (or a combination thereof), and which may include any combination of LANs, WANs, the Internet, etc. Control logic and/or data may be transmitted to and from computer system 700 via communication path 726.

Computer system 700 may also be any of a personal digital assistant (PDA), desktop workstation, laptop or notebook computer, netbook, tablet, smart phone, smart watch or other wearable, appliance, part of the Internet-of-Things, and/or embedded system, to name a few non-limiting examples, or any combination thereof.

Computer system 700 may be a client or server, accessing or hosting any applications and/or data through any delivery paradigm, including but not limited to remote or distributed cloud computing solutions; local or on-premises software (“on-premise” cloud-based solutions); “as a service” models (e.g., content as a service (CaaS), digital content as a service (DCaaS), software as a service (SaaS), managed software as a service (MSaaS), platform as a service (PaaS), desktop as a service (DaaS), framework as a service (FaaS), backend as a service (BaaS), mobile backend as a service (MBaaS), infrastructure as a service (IaaS), etc.); and/or a hybrid model including any combination of the foregoing examples or other services or delivery paradigms.

Any applicable data structures, file formats, and schemas in computer system 700 may be derived from standards including but not limited to JavaScript Object Notation (JSON), Extensible Markup Language (XML), Yet Another Markup Language (YAML), Extensible Hypertext Markup Language (XHTML), Wireless Markup Language (WML), MessagePack, XML User Interface Language (XUL), or any other functionally similar representations alone or in combination. Alternatively, proprietary data structures, formats or schemas may be used, either exclusively or in combination with known or open standards.

In some embodiments, a tangible, non-transitory apparatus or article of manufacture comprising a tangible, non-transitory computer useable or readable medium having control logic (software) stored thereon may also be referred to herein as a computer program product or program storage device. This includes, but is not limited to, computer system 700, main memory 708, secondary memory 710, and removable storage units 718 and 722, as well as tangible articles of manufacture embodying any combination of the foregoing. Such control logic, when executed by one or more data processing devices (such as computer system 700 or processor(s) 704), may cause such data processing devices to operate as described herein.

The embodiments may further be described using the following clauses:
1. A method comprising:
   producing a first alignment mark to be used on a substrate, the first alignment mark comprising a topology of at least two pixels having different properties;
   determining one or more properties of each of the at least two pixels;
   optimizing the topology of the first alignment mark based on the one or more properties of the at least two pixels; and
   forming a second alignment mark, based on optimizing the first alignment mark, on the substrate.
2. The method of clause 1, wherein the optimizing the topology of the first alignment mark comprises determining a far-field pattern for radiation diffracted by the first alignment mark.
3. The method of clause 2, wherein the optimizing the topology of the first alignment mark comprises defining a cost function based on the far-field pattern.
4. The method of clause 3, wherein the optimizing the topology of the first alignment mark comprises minimizing the cost function based on one or more optimization goals.
5. The method of clause 4, wherein an optimized topology is automatically identified by optimizing the cost function along one or more parameters.
6. The method of clause 1, wherein:
   the at least two pixels comprise at least a first pixel and a second pixel, and
   the one or more properties includes an index of refraction, a material forming each pixel, and/or an etch depth of each pixel.
7. The method of clause 6, wherein:
   the first pixel has a first index of refraction, and
   the second pixel has a second index of refraction that is different from the first index of refraction.
8. The method of clause 7, wherein a far-field pattern for radiation diffracted by the first alignment mark is calculated using Fourier optics or full-wave simulations.
9. The method of clause 8, wherein:
   a cost function based on the far-field pattern is defined as

$$F ( ϕ ( {θ}_{x} , {θ}_{y} ) , ε ( {x}_{m} , {y}_{n} ) , [ {x}_{0} , {y}_{0} = α {x}_{0} + β ] )$$

where F is the cost function, ε is the permittivity of either of the two materials, and y₀=αx₀+β is a scanning function.
10. The method of clause 9, wherein:
   the topology of the first alignment mark is optimized by minimizing the cost function to variation of the incident field, mark topology, and scanning function.
11. The method of clause 1, wherein the optimizing the topology of the first alignment mark comprises determining a subpattern of the plurality of pixels in a unit cell of the first alignment mark.
12. The method of clause 1, wherein:
   the first alignment mark comprises a plurality of unit cells, and
   the optimizing the topology of the first alignment mark comprises determining a symmetry of the unit cells.
13. The method of clause 12, wherein the symmetry of each unit cell is periodic, semi-periodic, or non-periodic.
14. The method of clause 12, wherein the plurality of unit cells are arranged to have a centro-symmetric symmetry about a center of the alignment mark, an inversion or rotational symmetry about a non-centric point of the alignment mark, a mirror symmetry, or a combination thereof, or to have no symmetry.
15. The method of clause 1, wherein the forming the second alignment mark comprises depositing the at least two pixels by depositing at least a first material and a second material on the substrate.
16. The method of clause 15, wherein the first material and the second material are a dielectric or a metal.
17. A metrology system comprising:
   an illumination system configured to generate a beam of radiation;
   a projection system configured to project the beam of radiation onto an alignment mark on a substrate; and
   a detector configured to detect a position of the substrate by measuring a position of the alignment mark by measuring radiation diffracted by the alignment mark, wherein
   the alignment mark comprises an optimized topology defined by at least two pixels having different properties.
18. The metrology system of clause 17, wherein:
   the at least two pixels comprise at least a first pixel and a second pixel.
19. The metrology system of clause 18, wherein the first pixel has a first index of refraction and the second pixel has a second index of refraction that is different from the first index of refraction.
20. The metrology system of clause 17, wherein the alignment mark comprises a plurality of unit cells.
21. The metrology system of clause 20, wherein a symmetry of each unit cell of the alignment mark is periodic, semi-periodic, or non-periodic.
22. The metrology system of clause 20, wherein the plurality of unit cells are arranged to have a centro-symmetric symmetry about a center of the alignment mark, an inversion or rotational symmetry about a non-centric point of the alignment mark, a mirror symmetry, or a combination thereof
23. The metrology system of clause 19, wherein the first pixel is formed of a first material and the second pixel is formed of a second material that is different from the first material.
24. The metrology system of clause 23, wherein the first material and the second material are a dielectric or a metal.
25. An alignment mark formed on a substrate according to the method of clause 1.
26. A lithographic system comprising the metrology system of clause 17.
27. A method comprising:
   receiving a first alignment mark to be used on a substrate, the first alignment mark comprising a topology of at least two pixels having different properties;
   determining one or more properties of each of the at least two pixels;
   optimizing the topology of the first alignment mark based on the one or more properties of the at least two pixels; and
   storing or displaying a set of values used to form a second alignment mark having the optimized topology.
28. A non-transitory computer readable medium comprising a set of instructions that, when executed by a processor, cause the processor to execute operations comprising:
   receiving a first alignment mark to be used on a substrate, the first alignment mark comprising a topology of at least two pixels having different properties;
   determining one or more properties of each of the at least two pixels;
   optimizing the topology of the first alignment mark based on the one or more properties of the at least two pixels; and
   storing or displaying a set of values used to form a second alignment mark having the optimized topology.
29. A processor configured to execute processes comprising:
   receiving a proposed alignment mark to be used on a substrate, the proposed alignment mark comprising a topology of at least two pixels having different properties;
   determining one or more properties of each of the at least two pixels;
   optimizing the topology of the proposed alignment mark based on the one or more properties of the at least two pixels; and
   storing or displaying a set of values used to form an alignment mark having the optimized topology.

Based on the teachings contained in this disclosure, it will be apparent to persons skilled in the relevant art(s) how to make and use embodiments of this disclosure using data processing devices, computer systems and/or computer architectures other than that shown in FIG. 7. In particular, embodiments can operate with software, hardware, and/or operating system implementations other than those described herein.

Although specific reference can be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, LCDs, thin-film magnetic heads, etc. The skilled artisan will appreciate that, in the context of such alternative applications, any use of the terms “wafer” or “die” herein can be considered as specific examples of the more general terms “substrate” or “target portion”, respectively. The substrate referred to herein can be processed, before or after exposure, in for example a track unit (a tool that typically applies a layer of resist to a substrate and develops the exposed resist) and/or a metrology unit. Where applicable, the disclosure herein can be applied to such and other substrate processing tools. Further, the substrate can be processed more than once, for example in order to create a multi-layer IC, so that the term substrate used herein may also refer to a substrate that already contains multiple processed layers.

Although specific reference may have been made above to the use of embodiments of the present disclosure in the context of optical lithography, it will be appreciated that the present disclosure can be used in other applications, for example imprint lithography, and where the context allows, is not limited to optical lithography. In imprint lithography a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present disclosure is to be interpreted by those skilled in relevant art(s) in light of the teachings herein.

The terms “radiation,” “beam,” “light,” “illumination,” or the like can be used herein to refer to one or more types of electromagnetic radiation, for example, ultraviolet (UV) radiation (for example, having a wavelength λ of 365, 248, 193, 157 or 126 nm), extreme ultraviolet (EUV or soft X-ray) radiation (for example, having a wavelength in the range of 5-100 nm such as, for example, 13.5 nm), or hard X-ray working at less than 5 nm, as well as particle beams, such as ion beams or electron beams. Generally, radiation having wavelengths between about 400 to about 700 nm is considered visible radiation; radiation having wavelengths between about 780-3000 nm (or larger) is considered IR radiation. UV refers to radiation with wavelengths of approximately 100-400 nm. Within lithography, the term “UV” also applies to the wavelengths that can be produced by a mercury discharge lamp: G-line 436 nm; H-line 405 nm; and/or, I-line 365 nm. Vacuum UV, or VUV (i.e., UV absorbed by gas), refers to radiation having a wavelength of approximately 100-200 nm. Deep UV (DUV) generally refers to radiation having wavelengths ranging from 126 nm to 428 nm, and in some aspects, an excimer laser can generate DUV radiation used within a lithographic apparatus. In some embodiments, inspection, alignment, and/or metrology may be performed using, for example, radiation having a wavelength ranging from 400 nm to 900 nm. It should be appreciated that radiation having a wavelength in the range of, for example, 5-20 nm relates to radiation with a certain wavelength band, of which at least part is in the range of 5-20 nm.

Although some aspects of the present disclosure are described in the context of lithographic apparatuses in the manufacture of ICs, it should be understood that lithographic systems and alignment and metrology systems described herein can be used in other applications, for example, in the manufacture of integrated optical systems, guidance and detection patterns for magnetic domain memories, flat-panel displays, LCDs, thin-film magnetic heads, etc. Those skilled in the art will appreciate that, in the context of such alternative applications, any use of the terms “wafer” or “die” herein can be considered as specific examples of the more general terms “substrate” or “target portion”, respectively. A substrate can be processed before or after exposure in, for example, a track unit (a tool that typically applies a layer of resist to a substrate and develops the exposed resist) and/or a metrology unit. Where applicable, aspects disclosed herein can be applied to such and other substrate processing tools. Furthermore, a substrate can be processed more than once, for example in order to create a multi-layer IC, so that the term substrate used herein can also refer to a substrate that already contains multiple processed layers.

Furthermore, although some aspects of the present disclosure are described above in the context of lithography, it should be understood that aspects of the present disclosure are not limited to lithography. For example, in imprint lithography, a topography in a patterning device defines the pattern created on a substrate. The topography of the patterning device can be pressed into a layer of resist supplied to the substrate whereupon the resist is cured by applying electromagnetic radiation, heat, pressure or a combination thereof. The patterning device is moved out of the resist leaving a pattern in it after the resist is cured.

It is to be understood that the phraseology or terminology herein is for the purpose of description and not of limitation, such that the terminology or phraseology of the present specification is to be interpreted by those skilled in relevant art(s) in light of the teachings herein.

The present disclosure has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed. The foregoing description of specific aspects will so fully reveal the general nature of the present disclosure that others can, by applying knowledge within the skill of the art, readily modify and/or adapt for various applications such specific aspects, without undue experimentation and without departing from the general concept of the present disclosure. Therefore, such adaptations and modifications are intended to be within the meaning and range of equivalents of the disclosed aspects, based on the teaching and guidance presented herein.

It is to be understood that the Detailed Description section, and not the Summary and Abstract sections, is intended to be used to interpret the claims. The Summary and Abstract sections can set forth one or more, but not necessarily all, aspects of the present disclosure as contemplated by the inventor(s), and thus, are not intended to limit the present disclosure and the appended claims in any way. The breadth and scope of the protected subject matter should not be limited by any of the above-described aspects, but should be defined in accordance with the following claims and their equivalents.

1. A method comprising:
producing a first alignment mark to be used on a substrate, the first alignment mark comprising a topology of at least two pixels having different properties;
determining one or more properties of each of the at least two pixels;
optimizing the topology of the first alignment mark based on the one or more properties of the at least two pixels; and
forming a second alignment mark, based on optimizing the first alignment mark, on the substrate.

2. The method of claim 1, wherein the optimizing the topology of the first alignment mark comprises determining a far-field pattern for radiation diffracted by the first alignment mark.

3. The method of claim 2, wherein the optimizing the topology of the first alignment mark comprises defining a cost function based on the far-field pattern.

4. The method of claim 3, wherein the optimizing the topology of the first alignment mark comprises minimizing the cost function based on one or more optimization goals.

5. The method of claim 4, wherein an optimized topology is automatically identified by optimizing the cost function along one or more parameters.

6. The method of claim 1, wherein:
the at least two pixels comprise at least a first pixel and a second pixel, and
the one or more properties includes an index of refraction, a material forming each pixel, and/or an etch depth of each pixel.

7. The method of claim 6, wherein:
the first pixel has a first index of refraction, and
the second pixel has a second index of refraction that is different from the first index of refraction.

8. The method of claim 7, wherein a far-field pattern for radiation diffracted by the first alignment mark is calculated using Fourier optics or full-wave simulations.

9. The method of claim 8, wherein:
a cost function based on the far-field pattern is defined as
$$F ( ϕ ( {θ}_{x} , {θ}_{y} ) , ε ( {x}_{m} , {y}_{n} ) , [ {x}_{0} , {y}_{0} = α {x}_{0} + β ] )$$
where F is the cost function, ε is the permittivity of either of the two materials, and y₀=αx₀+β is a scanning function.

10. The method of claim 9, wherein:
the topology of the first alignment mark is optimized by minimizing the cost function to variation of the incident field, mark topology, and scanning function.

11. The method of claim 1, wherein the optimizing the topology of the first alignment mark comprises determining a subpattern of the plurality of pixels in a unit cell of the first alignment mark.

12. The method of claim 1, wherein:
the first alignment mark comprises a plurality of unit cells, and
the optimizing the topology of the first alignment mark comprises determining a symmetry of the unit cells.

13. The method of claim 12, wherein the symmetry of each unit cell is periodic, semi-periodic, or non-periodic.

14. The method of claim 12, wherein the plurality of unit cells are arranged to have a centro-symmetric symmetry about a center of the alignment mark, an inversion or rotational symmetry about a non-centric point of the alignment mark, a mirror symmetry, or a combination thereof, or to have no symmetry.

15. The method of claim 1, wherein the forming the second alignment mark comprises depositing the at least two pixels by depositing at least a first material and a second material on the substrate.
